(19) United States
(12) Patent Application Publication
(10) Pub. No.: US 2007/0146062 A1
(43) Pub. Date: Jun. 28, 2007

(54) Active filer circuit for limiting band of input signal

(75) Inventors: Takeshi Otsuka, Hashima-shi (JP); Seiichi Banba, Ogaki-shi (JP)

Correspondence Address: MCDERMOTT WILL & EMERY LLP, 600 13TH STREET, N.W., WASHINGTON, DC, 20005-3096, US

(73) Assignee: SANYO ELECTRIC CO., LTD.

(21) Appl. No.: 11/646,414

(22) Filed: Dec. 28, 2006

(30) Foreign Application Priority Data
Dec. 28, 2005 (JP) 2005-378358

(51) Int. Cl. H03K 5/00

(52) U.S. Cl. 327/552

(57) ABSTRACT

A general purpose of the present invention is to stabilize a filter circuit to desired characteristics without increasing its circuit scale. An active filter unit includes a current control unit, a first gm-C filter unit, and a subsequent circuit. Using a signal output from a central control unit as an input, the current control unit outputs adjustment currents for adjusting gm values, corresponding to respective transconductance amplifiers, to the first gm-C filter unit. The subsequent circuit includes a load capacitance which is composed of an active element such as a transconductance amplifier. The first gm-C filter unit includes the plurality of transconductance amplifiers and a control unit which controls the gm values of the transconductance amplifiers. It limits the band of the signal output from a first filter signal selection unit, and outputs the result to the subsequent circuit.

### BACKGROUND OF THE INVENTION

1. Field of the Invention

The present invention relates to an analog circuit technology, and in particular to a filter circuit which limits a band of an input signal.

2. Description of the Related Art

Gm-C filters have excellent high-frequency and wide-band filter characteristics, and have recently been used as baseband filters to be mounted on communication apparatuses. A gm-C filter is composed of gm (hereinafter, also referred to as transconductance or transfer conductance) amplifiers and capacitive elements, and its filter characteristics are determined by the ratios between the gains of the gm amplifiers (hereinafter, referred to as gm values) and the capacitances. Due to significant variations in manufacturing, it has been necessary to control the gm values of the gm amplifiers in order to achieve filter characteristics with high precision. To address this problem, the gm values of the gm amplifiers have conventionally been controlled by adjusting the ratios between the gate widths and gate lengths of the MOS transistors that constitute the gm amplifiers (for example, see Japanese Patent Laid-Open Publication No. 2002-223148).

Under the circumstances, the inventor has recognized the following problem. That is, when the gate width and gate length of the MOS transistors are controlled, the parasitic capacitances of the MOS transistors can also increase in proportion to this level of control. This makes it difficult to achieve the desired filter characteristics with stability.

### SUMMARY OF THE INVENTION

The present invention has been developed in view of the foregoing circumstances, and a general purpose thereof is to provide a filter circuit which achieves the desired filter characteristics with stability without increasing the circuit scale.

To solve the foregoing problem, an active filter circuit according to an embodiment of the present invention includes: an input unit which inputs a predetermined signal; a plurality of active elements connected in series so that the active element to which the predetermined signal is input from the input unit comes first; an active element to which an output of the active element in the final stage out of the plurality of active elements is input; a plurality of capacitive elements formed on outputs of the respective plurality of active elements; and a control unit which supplies the plurality of active elements with adjustment currents corresponding to the respective active elements, thereby adjusting the gain of the plurality of active elements. Each of the plurality of active elements also receives a signal that is output from the active element itself or the active element at a subsequent stage. The ratios between the capacitances of the respective plurality of capacitive elements are related to the devices areas of the plurality of active elements and to the active element to which the output of the active element in the final stage is input.

In this instance, the “active elements” may include transistors. Examples thereof include a transconductance amplifier which consists of a plurality of transistors. The “plurality of capacitive elements formed on the outputs of the respective plurality of active elements” may refer to such an arrangement where the capacitive elements are connected to the output ends of the respective active elements. The capacitive elements may be arranged between the output ends of the active elements and earth (ground). The “active element to which the output of the active element in the final stage is input” may include a transistor that serves as a load capacitance to the active element in the final stage. The “device areas of the active elements” include, for example, the gate areas of the input terminals of transconductance amplifiers. According to this embodiment, the areas of the gate capacitances and the ratios of the capacitances of the respective filters are made constant with respect to each other. This makes it possible to keep the capacitances, including the parasitic capacitances, of the capacitive elements constant.

It should be appreciated that any combinations of the foregoing components, and any conversions of expressions of the present invention from/into methods, apparatuses, systems, recording media, computer programs, and the like are also intended to constitute applicable aspects of the present invention.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a diagram showing an example of configuration of a communication apparatus according to an embodiment of the present invention;

FIG. 2 is a diagram showing an example of configuration of a central control unit in FIG. 1;

FIGS. 3A and 3B are charts each showing examples of the filter characteristics of an active filter unit in FIG. 1;

FIG. 4 is a diagram showing an example of configuration of the active filter unit in FIG. 1;

FIGS. 5A to 5C are diagrams showing examples of configuration of a first gm-C filter unit in FIG. 4;

FIG. 6 is a diagram showing a modification of the active filter unit in FIG. 4;

FIG. 7 is a diagram showing an example of configuration of a second gm-C filter unit in FIG. 6;

FIG. 8 is a diagram showing another modification of the active filter unit in FIG. 4; and

FIG. 9 is a flowchart showing an example of operation of the central control unit in FIG. 2.

### DETAILED DESCRIPTION OF THE INVENTION

The invention will now be described by reference to the preferred embodiments. This does not intend to limit the scope of the present invention, but to exemplify the invention.

Before describing the embodiment in detail, the present invention will initially be overviewed. A communication apparatus 100 according to the embodiment of the present invention has a filter circuit which can actively adjust its filter characteristics. To “actively adjust” includes, for example, adjusting the filter characteristics automatically when the communication apparatus is powered on and when a change occurs in the use environment of the communication apparatus, or the temperature environment in particular. When adjusting the filter characteristics, a plurality of adjustment signals generated by a PLL (Phase-Locked Loop) are initially switched in turn to measure the attenuations of their respective signal strengths, and to calculate differences therebetween. Then, the cutoff frequency of the filter circuit is estimated from the differences calculated. A frequency deviation from a desired cutoff frequency is detected, and the filter characteristics are adjusted. Further details of this arrangement will be given later.

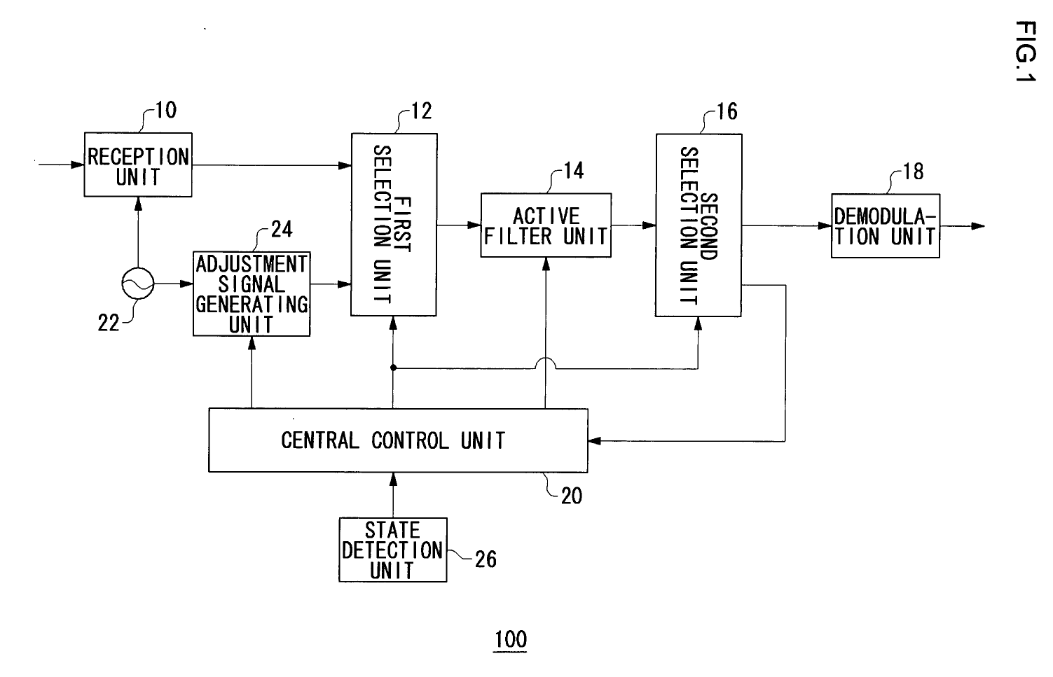

FIG. 1 is a diagram showing an example of configuration of such a communication apparatus 100 according to the embodiment of the present invention. The communication apparatus 100 includes a reception unit 10, a first filter signal selection unit 12, an active filter unit 14, a second filter signal selection unit 16, a demodulation unit 18, a central control unit 20, a frequency oscillation unit 22, an adjustment signal generating unit 24, and a state detection unit 26.

The frequency oscillation unit 22 generates a predetermined frequency signal, and outputs it to the reception unit 10 and the adjustment signal generating unit 24. The reception unit 10 receives a signal that is transmitted from a party which is holding communication with the communication apparatus 100. The reception unit 10 also performs band-limiting processing, amplification processing, and the like on the received signal by using a not-shown IF filter, amplifier, or the like. In addition to this, a not-shown mixer mixes the frequency signal output from the frequency oscillation unit 22 and the reception signal received by the reception unit 10 for downconversion, and outputs the downconverted signal to the first filter signal selection unit 12.

The adjustment signal generating unit 24 includes a plurality of not-shown frequency dividers. Using the frequency signal output from the frequency oscillation unit 22 as an input, the adjustment signal generating unit 24 generates signals having different respective frequencies (hereinafter, referred to as “adjustment signals”) through the plurality of frequency dividers. The “adjustment signals” include a signal having a frequency higher than a cutoff frequency desired by the active filter unit 14, a signal having the same frequency as the cutoff frequency, and a signal having a frequency lower than the cutoff frequency. The adjustment signal generating unit 24 also includes a not-shown adjustment signal selection unit, which selects an adjustment signal designated by the central control unit 20 (to be described later) and outputs it to the first filter signal selection unit 12.

According to an instruction from the central control unit 20 (to be described later), the first filter signal selection unit 12 selects either one of the signal output from the reception unit 10 and the adjustment signal output from the adjustment signal generating unit 24, and outputs the selected signal to the active filter unit 14. The active filter unit 14 performs filter processing, such as band-limiting processing, on the signal output from the first filter signal selection unit 12, and outputs the result to the second filter signal selection unit 16. The active filter unit 14 also adjusts its filter characteristics based on a signal that is intended to adjust the filter characteristics output from the central control unit 20 (to be described later). Further details of this adjustment will be given later. The second filter signal selection unit 16 outputs the signal output from the active filter unit 14 to the demodulation unit 18 or the central control unit 20, based on a signal given from the central control unit 20 (to be described later).

The central control unit 20 sends selection signals to the first filter signal selection unit 12 and the second filter selection unit 16. For example, when this communication apparatus 100 is powered on or a change occurs in the use environment of the communication apparatus 100, or in the temperature environment in particular, the central control unit 20 sends a selection signal to the first filter signal selection unit 12 so that it outputs the signal output from the adjustment signal generating unit 24 to the active filter unit 14. The central control unit 20 also sends a selection signal to the second filter signal selection unit 16 so that it outputs the signal output from the active filter unit 14 to the central control unit 20. In this instance, if “this communication apparatus 100 is powered on or a change occurs in the use environment of the communication apparatus 100, or in the temperature environment in particular,” may be determined by such components as the state detection unit 26 which manages the state of the communication apparatus 100. The determination is then notified to the central control unit 20. In such a case, the state detection unit 26 may have a mechanism for measuring the temperature of the communication apparatus 100, so that it measures the temperature at regular intervals and notifies the temperature measurements to the central control unit 20. Interval averages or moving averages of the temperature measurements may be notified to the central control unit 20. Moreover, the temperature measurements, averages, or the like may be compared with a threshold so that the central control unit 20 is notified only when the temperature changes. It should be appreciated that the state detection unit 26 may be integrated with the central control unit 20.

Unless “this communication apparatus 100 is powered on or a change occurs in the use environment of the communication apparatus 100, or in the temperature environment in particular,” the central control unit 20 sends a selection signal to the first filter signal selection unit 12 so that it outputs the signal output from the reception unit 10 to the active filter unit 14. The central control unit 20 also sends a signal to the second filter signal selection unit 16 so that it outputs the signal output from the active filter unit 14 to the demodulation unit 18. The following description will deal with the case where “this communication apparatus 100 is powered on or a change occurs in the use environment of the communication apparatus 100, or in the temperature environment in particular.”

The central control unit 20 gives the adjustment signal generating unit 24 an instruction to select any one of the adjustment signals generated by the adjustment signal generating unit 24. The central control unit 20 then measures the signal strength of the adjustment signal that is output through the first filter signal selection unit 12, the active filter unit 14, and the second filter signal selection unit 16, and determines the attenuation thereof. The “attenuation” includes the ratio between the signal strength of the adjustment signal yet to be filter-processed by the active filter unit 14 and that of the adjustment signal filter-processed by the active filter unit 14, and also includes the amount of difference therebetween. The central control unit 20 estimates the cutoff frequency of the active filter unit 14 from that difference therebetween. Moreover, the central control unit 20 also determines a difference between the cutoff frequency estimated and a desired cutoff frequency of the active filter unit 14, and adjusts the filter characteristics accordingly. Further details of this arrangement will be given later.

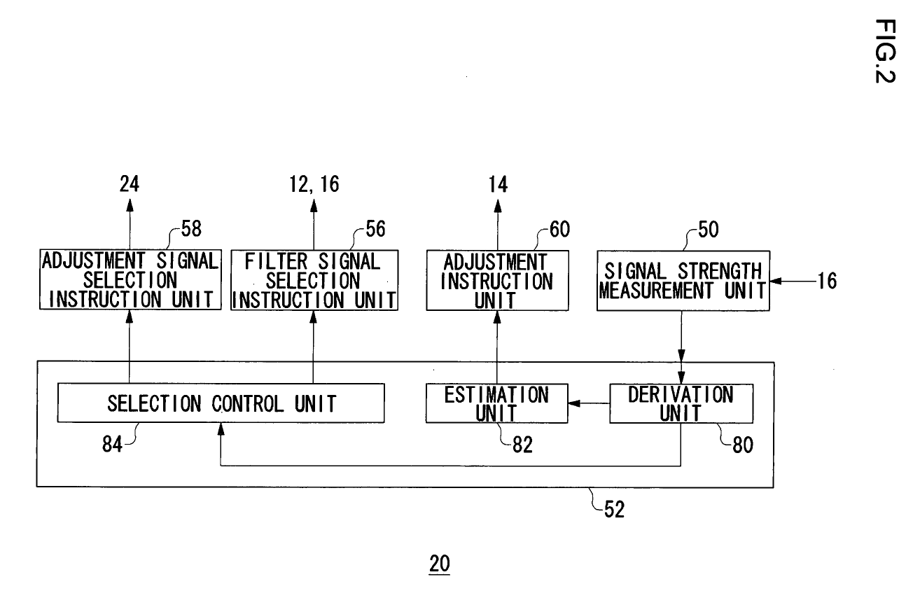

FIG. 2 is a diagram showing an example of the configuration of the central control unit 20 shown in FIG. 1. The central control unit 20 includes a signal strength measurement unit 50, a filter characteristic adjustment unit 52, a filter signal selection instruction unit 56, an adjustment signal selection instruction unit 58, and an adjustment instruction unit 60. The filter characteristic adjustment unit 52 includes a derivation unit 80, an estimation unit 82, and a selection control unit 84. The central control unit 20 starts operation based on an instruction from the state detection unit 26. Specifically, the selection control unit 84 makes the filter signal selection instruction unit 56 send a selection signal so that the active filter unit 14 performs filter processing on an adjustment signal, not on the reception signal.

The signal strength measurement unit 50 measures the signal strength of the adjustment signal output from the second filter signal selection unit 16. The signal strength measurement unit 50 also measures the signal strength of the signal yet to be filter-processed by the active filter unit 14. In this instance, the signal strengths may be expressed by any index that indicates the intensity of a signal. Examples thereof include RSSI (Received Signal Strength Indicator) and SNR (Signal to Noise Ratio).

The derivation unit 80 subtracts the strengths of a plurality of adjustment signals filter-processed by the active filter unit 14 from the strengths of the adjustment signals before the filter processing, measured by the signal strength measurement unit 50, and determines the attenuations of the respective signal strengths. Consider the case where a “difference-related threshold” of attenuations, previously stored in a memory or the like, and a difference between the attenuations determined for the respective adjustment signals are compared and it is determined that the difference falls below the “difference-related threshold.” In such situations, i.e., where it is considered difficult to accurately estimate the cutoff frequency, the selection control unit 84 makes the adjustment signal selection instruction unit 58 send a selection signal to the adjustment signal generating unit 24 so that it generates another adjustment signal. The same processing is subsequently repeated until the difference between the signal strengths of the adjustment signals exceeds the predetermined threshold.

The derivation unit 80 also compares a difference in attenuation in the active filter unit 14 (hereinafter, referred to as the “actual difference”) with a difference in attenuation in an ideal conceptual filter that has a desired cutoff frequency (hereinafter, referred to as the “ideal difference”). Based on the result of this comparison, the derivation unit 80 determines whether or not the “actual difference” falls within an allowable range. The allowable range refers to a range having an upper limit that is determined by adding a predetermined first allowable amount of error to the “ideal difference,” and a lower limit that is determined by subtracting a predetermined second allowable amount of error from the “ideal difference.” If the difference in attenuation falls within the allowable range, the selection control unit 84 makes the filter signal selection instruction unit 56 output selection signals to the first filter signal selection unit 12 and the second filter signal selection unit 16 so that they output the reception signal from the reception unit 10 to the active filter unit 14 and the demodulation unit 18.

In this instance, the selection control unit 84 may select the adjustment signals in any order. The signals may also be selected in ascending or descending order of frequency. The last adjustment signal used in the past may be selected by priority. When selecting “another adjust signal,” the selection control unit 84 may select an adjustment signal such that its frequency is closer to the desired cutoff frequency than those of the adjustment signals previously selected are.

The estimation unit 82 estimates the cutoff frequency of the active filter unit 14 based on the differences between the attenuations of the respective signal strengths determined by the derivation unit 80. Moreover, the adjustment instruction unit 60 determines a difference between the estimated cutoff frequency and the desired cutoff frequency of the active filter unit 14, and adjusts the filter characteristics accordingly.

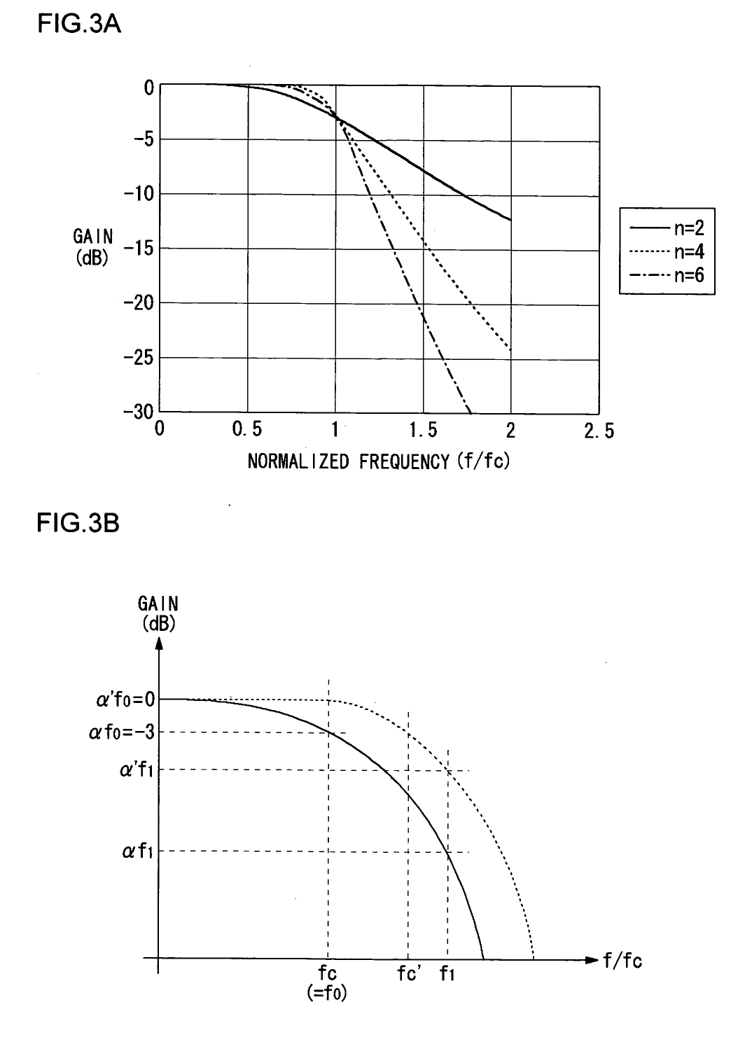

A description will now be given with reference to FIGS. 3A and 3B of the operation of the filter characteristic adjustment unit 52 in case that the active filter unit 14 is a low-pass filter. FIGS. 3A and 3B are graphs showing examples of the filter characteristics of the active filter unit 14 shown in FIG. 1. In FIGS. 3A and 3B, the vertical axis indicates the amplitude (gain) of the output signal, and the horizontal axis indicates the normalized frequency.

FIG. 3A shows the filter characteristics when the active filter unit 14 has a filter order of n and a cutoff frequency of f_{c}. The characteristics shown in FIG. 3A are expressed by the following equation (1):

$$α = 10 \cdot log [ \frac{1}{1 + {( f / {f}_{c} )}^{2 n}} ] \qquad ( 1 )$$

where α is the gain. It should be noted that α takes zero or a negative value. In other words, the absolute value of α shows the attenuation.

Now, suppose that four adjustment signals having respective frequencies of 60 MHz, 120 MHz, 240 MHz, and 480 MHz are used. Also suppose that n=4. Then, the ideal gains of the active filter unit 14 at f_{c}=240 MHz when the respective adjustment signals are input thereto are −0.0169 dB, −0.263 dB, −3.01 dB, and −12.3 dB.

FIG. 3A and equation (1) show that the active filter unit 14 has an attenuation of approximately 3 dB at the cutoff frequency f_{c}, irrespective of the filter order n. In other words, at the cutoff frequency, the amplitude of the signal output from the filter is approximately half that of the signal yet to be input to the filter. At and above the cutoff frequency, the attenuation of the active filter increases with the frequency in a generally linearly trend on the log scale. Moreover, if the frequency is sufficiently lower than the cutoff frequency f_{c} or if the filter order n is sufficiently high, the attenuation α is reduced to almost zero.

Consequently, when an adjustment signal having the same frequency as the desired cutoff frequency f_{c} is input to the active filter unit 14, the cutoff frequency f_{c}′ of the active filter unit 14 may be considered to fall below the desired cutoff frequency f_{c} if the attenuation is 3 dB or higher. At attenuations below 3 dB, on the other hand, the cutoff frequency f_{c}′ may be considered to exceed the desired cutoff frequency f_{c}.

A description will now be given with reference to FIG. 3B of an actual example of how to determine a frequency deviation between the cutoff frequency of the active filter unit 14 and the desired cutoff frequency. In FIG. 3B, the solid line shows the filter characteristic when the active filter unit 14 has the desired cutoff frequency. The broken line shows an example of filter characteristics of the active filter unit 14. Suppose here that the desired cutoff frequency f_{c}=240 MHz, and the filter order n=4.

Take the case where adjustment signals having respective frequencies of f₀(=f_{c}) and f₁ are input to the active filer unit 14 that has the desired cutoff frequency. For the adjustment signal of f₀, the derivation unit 80 determines an attenuation of α_{f0}=3 dB. For the adjustment signal of f₁, the derivation unit 80 determines an attenuation of α_{f1}. As an example, assuming that f₀=240 MHz and f₁=480 Hz, the difference between the attenuations is given by the following equation:
α_{f1}−α_{f0}=12.3−3.01=9.29. (2)

Now, consider the case where the adjustment signals having respective frequencies of f₀(=f_{c}) and f₁ are input to the active filter unit 14 that has a cutoff frequency of f_{c}′. Then, the derivation unit 80 determines an attenuation of α′_{f0} for the adjustment signal of f₀, and an attenuation of α′_{f1} for the adjustment signal of f₁. In this instance, the difference between α′_{f0} and α′_{f1} is expressed by the following equation, which can be solved for f_{c}′ to determine the difference from the desired cutoff frequency:

$${α}_{{f}_{θ}} - {α}_{{f}_{1}} = 10 \cdot log [ \frac{1}{1 + {( \frac{{f}_{θ}}{{f}_{c}^{′}} )}^{8}} ] - 10 \cdot log [ \frac{1}{1 + {( \frac{{f}_{1}}{{f}_{c}^{′}} )}^{8}} ] \qquad ( 3 )$$

It should be appreciated that when f_{c}=f_{c}′, i.e., the attenuation differences calculated by equations (2) and (3) are the same, then the active filter unit 14 naturally has the desired filter characteristic. In such cases, the estimation unit 82 will not instruct the adjustment instruction unit 60 to adjust the filter characteristics. The same holds for the cases of f_{c}=f_{c}′±α if the errors of α are allowable. In such cases, the selection control unit 84 makes the filter signal selection instruction unit 56 output selection signals to the first filter signal selection unit 12 and the second filter signal selection unit 16 so that they output the reception signal from the reception unit 10 to the active filter unit 14 and the demodulation unit 18. The reason for this is that the filter adjustment is unnecessary, or already completed.

Note that the foregoing cases where “the difference between the attenuations determined by the respective adjustment signals is smaller than a predetermined threshold” and where “it is considered difficult to accurately estimate the cutoff frequency” refer to situations where the attenuation difference determined by the derivation unit 80 is near zero. For example, if two adjustment signals have frequencies of f₀ and f₁, and the cutoff frequency f_{c}′ of the active filter unit 14 is greatly different from the two frequencies, the attenuation difference approaches zero. Such situations can occur when both f₀ and f₁ are covered by the passband of the active filter unit 14, when both f₀ and f₁ are covered by stopbands, or the like.

In such cases, it is necessary to use adjustment signals having frequencies that increase the attenuation difference. If the cutoff frequency f_{c}′ of the active filter unit 14 is higher than or equal to the frequency of either one of the adjustment signals and is lower than the frequency of the other adjustment signal, the attenuation difference becomes greater than in other cases. The selection control unit 84 is thus desirably operated to select such adjustment signals. This makes it possible to determine f_{c}′ with high accuracy, and based on this, the adjustment instruction unit 60 adjusts the filter characteristics of the active filter unit 14.

The foregoing description has dealt with the case where the cutoff frequency is estimated with high accuracy based on the difference between the attenuations of two adjustment signals because the actual circuit can contain some fixed loss or gain. This is not intended to be restrictive, however. A single adjustment signal only may be used to estimate f_{c}′. In this case, the following equation may be solved for f_{c}′:

$${α}_{{f}_{θ}} = 10 \cdot log [ \frac{1}{1 + {( \frac{{f}_{θ}}{{f}_{c}^{′}} )}^{8}} ] \qquad ( 4 )$$

A description will now be given of how to adjust the filter characteristics when the active filter unit 14 is a gm-C filter. In a gm-C filter, the operating currents of the mounted amplifiers, such as transconductance amplifiers, are changed to adjust the gm values, thereby adjusting the cutoff frequency to a desired value. Note that gm-C filters sometimes have variations of ±10% or so in the gm values and in the capacitances of the capacitors C, which cause changes in the cutoff frequency.

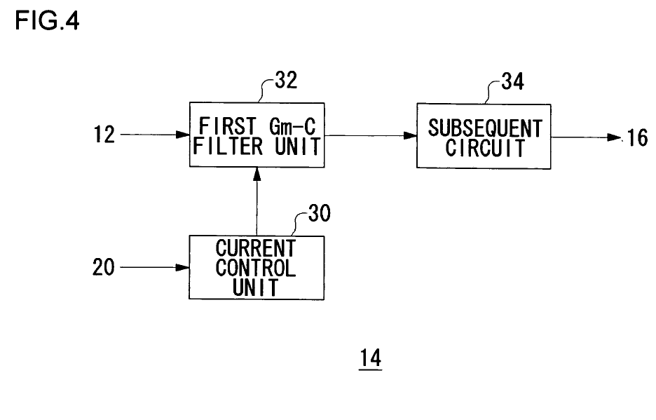

FIG. 4 is a diagram showing an example of the configuration of the active filter unit 14 shown in FIG. 1. The active filter unit 14 includes a current control unit 30, a first gm-C filter unit 32, and a subsequent circuit 34. The current control unit 30 receives the signal output from the central control unit 20, and outputs adjustment currents for adjusting gm values to the first gm-C filter unit 32. Since the first gm-C filter unit 32 includes a plurality of transconductance amplifiers, the current control unit 30 supplies adjustment currents corresponding to the respective transconductance amplifiers. The subsequent circuit 34 includes a load capacitance which is composed of an active element such as a transconductance amplifier. The subsequent circuit 34 may be any of a buffer circuit, an amplifier circuit, a level shifter circuit, a filter circuit, and the like, and may have any function as long as it can be used as a load capacitance. For the sake of simplicity, the following description will dealt with the case where the active element is a transconductance amplifier. The present invention is not limited thereto, however.

The first gm-C filter unit 32 includes a plurality of transconductance amplifiers and a control unit which controls the gm values of the transconductance amplifiers. It limits the band of the signal output from the first filter signal selection unit 12, and outputs the result to the subsequent circuit 34. As will be detailed later, the active filter unit 14 according to the embodiment of the present invention is designed to relate the capacitances of the respective capacitor elements and the gate sizes of the transconductance amplifiers to each other. This makes it possible to achieve desired filter characteristics by adjusting the gm values of the active elements by constant ratios even if the parasitic capacitances of the transconductance amplifiers have a considerable impact.

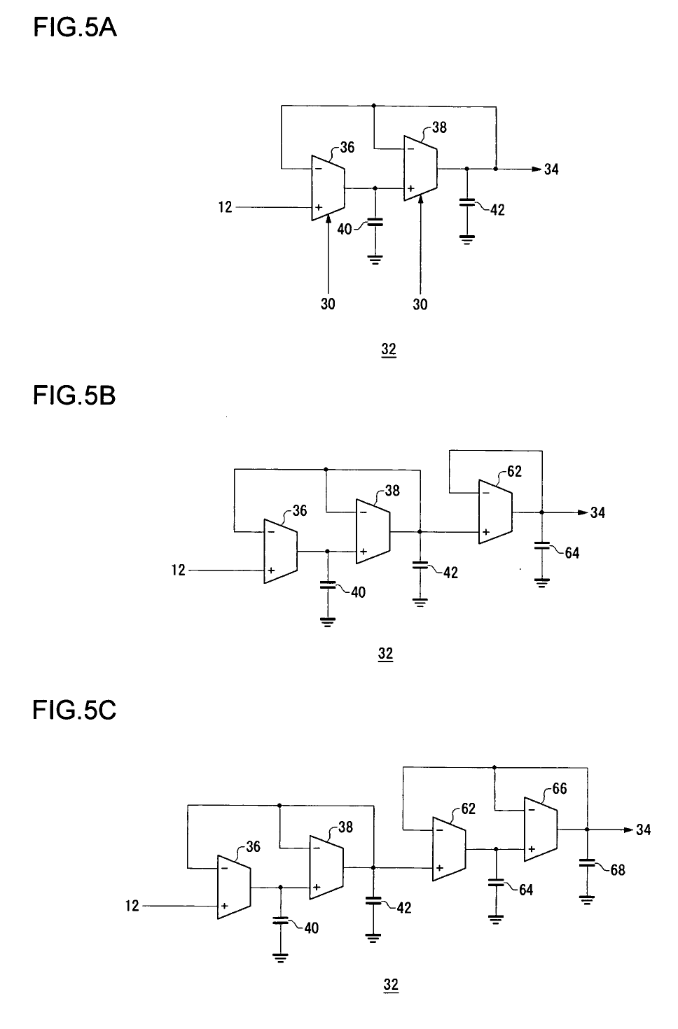

FIGS. 5A to 5C are diagrams showing examples of the configuration of the first gm-C filter unit 32 shown in FIG. 4. The first gm-C filter unit 32 shown in FIG. 5A is a second-order LPF (Low-Pass Filter) which includes a first transconductance amplifier 36, a second transconductance amplifier 38, a first capacitive element 40, and a second capacitive element 42. A signal to be band-limited is input from the first filter signal selection unit 12 to the first transconductance amplifier 36. The first transconductance amplifier 36 also receives the signal output from the second transconductance amplifier 38. The second transconductance amplifier 38 is connected with the output of the first transconductance amplifier 36. The second transconductance amplifier 38 also receives the signal output from itself. The first capacitive element 40 is arranged between the output of the first transconductance amplifier 36 and earth. The second capacitive element 42 is connected between the output of the second transconductance amplifier 38 and earth. In this instance, the ratio of the device area of the second transconductance amplifier 38 with respect to the total device area of the first transconductance amplifier 36, the second transconductance amplifier 38, and a third transconductance amplifier is related to the ratio of the capacitance of the first capacitive element 40 with respect to the capacitance of the second capacitive element 42 so that the ratios coincide with each other. It should be appreciated that “the device area of a transconductance amplifier” includes the gate areas of its input terminals or the like.

A description of the first gm-C filter unit will now be given in detail. The transfer function of the first gm-C filter unit 32 shown in FIG. 5A is expressed by the following equations:

$$\begin{matrix}H ( s ) = \frac{{ω}_{0}^{2}}{{s}^{2} + \frac{{ω}_{0}}{Q} s + {ω}_{0}^{2}} & ( 5 ) \\ {ω}_{0} = \sqrt{\frac{gm 1 \cdot gm 2}{C 1 \cdot C 2}} & ( 6 ) \\ Q = \sqrt{\frac{C 2 \cdot gm 1}{C 1 \cdot gm 2}} & ( 7 )\end{matrix}$$

In this instance, gm1 and gm2 represent the current gains of the first transconductance amplifier 36 and the second transconductance amplifier 38, respectively. C1 and C2 are the capacitances of the first capacitive element 40 and the second capacitive element 42, respectively. Moreover, ω₀ and Q given by equations (6) and (7) are indexes for determining a desired filter characteristic.

Consider the case where the first transconductance amplifier 36 has a gate capacitance of C1′, and the second transconductance amplifier 38 has a gate capacitance of C2′. The gate capacitances include parasitic capacitances of the MOS transistors. The device area S1 of the first transconductance amplifier 36, the device area S2 of the second transconductance amplifier 38, and the device area S3 of the not-shown third transconductance amplifier which is formed inside the subsequent circuit 34 are related to each other as shown by the following equation:
S1+S2+S3=k·S2. (8)

From the following equation:
S1+S3=(k−1)·S2. (9)
This derives the condition k>1.

The gate capacitances of the first transconductance amplifier 36, the second transconductance amplifier 38, and the third transconductance amplifier are in proportion to the respective gate areas. Assuming that the input transistor of each of the transconductance amplifiers has a gate capacitance of C per unit area, equation (8) yields:
C·S1+C·S2+C·S3=k·C·S2. (10)
The capacitances C1′ and C2′ at the respective output ends of the first transconductance amplifier 36 and the second transconductance amplifier 38 are given by the following equations:
C1′=C1+C·S2, and (11)
C2′=C2+C·S1+C·S2+C·S3. (12)

Assuming that C2=k·C1, the substitution of equation (10) into equation (12) shows C2′ as follows:

$$\begin{matrix}C {2}^{′} = k \cdot C 1 + k \cdot C \cdot S 2 \\ = k \cdot ( C 1 + C \cdot S 2 )\end{matrix} \qquad ( 13 )$$

As a result, C2′=k·C1′. The ratio between C2′ and C1′ is thus equivalent to that of C2 and C1 even when the input gate capacitances are taken into account.

Since the capacitances are equivalent:
C1′=x·C1, and (14)
C2′=x·C2, (15)
where x is the rate of increase of the capacitance due to the gate capacitances. gm1 and gm2 may therefore be multiplied by x to adjust the desired filter characteristics without changing ω₀ and Q in equations (6) and (7). In other words, when the input gate areas of the respective transconductance amplifiers and the capacitances of the capacitive elements are related and set as described above, the gm values can be adjusted to make the filter characteristics insusceptible to parasitic capacitances ascribable to the gate capacitances. Since the filter characteristics are insusceptible to the gate capacitances, the gm values can be controlled to adjust equations (6) and (7). This makes it possible to accurately adjust the filter characteristics.

A description will now be given of the adjustment when the first transconductance amplifier 36 and the second trans conductance amplifier 38 are MOS transistors. The gm value of an MOS transistor is in proportion to SQRT(Id·W/L), where Id is the drain current, W is the gate width, and L is the gate length. SQRT(X) represents a function for calculating the square root of X. By supplying the drain currents Id of the transconductance amplifiers to be adjusted to the transconductance amplifiers, the current control unit 30 can thus control the gm values and, by extension, adjust the filter characteristics.

The first gm-C filter unit 32 shown in FIG. 5B is a third-order LPF which is formed by adding a fourth transconductance amplifier 62 and a third capacitive element 64 to the first gm-C filter unit 32 shown in FIG. 5A. The fourth transconductance amplifier 62 is arranged between the second transconductance amplifier 38 and the third transconductance amplifier. The fourth transconductance amplifier 62 also receives the signal that is output from itself. The third capacitive element 64 is arranged between the fourth transconductance amplifier 62 and earth.

In this instance, the ratio of the device area of the second transconductance amplifier 38 with respect to the total device area of the third transconductance amplifier and the fourth transconductance amplifier 62 is related to the ratio of the capacitance of the first capacitive element 40 with respect to the capacitance of the third capacitive element 64 so that the ratios coincide with each other. In addition to this, the ratio of the device area of the second transconductance amplifier 38 with respect to the total device area of the first transconductance amplifier 36, the second transconductance amplifier 38, and the fourth transconductance amplifier 62 is related to the ratio of the capacitance of the first capacitive element 40 with respect to the capacitance of the second capacitive element 42 so that the ratios coincide with each other. To put it another way, the relationships satisfy the following equations:
C1:C2:C3=1:k2:k3, (16)
S1+S2+S4=k2·S2, and (17)
S3+S4=k3·S2. (18)

Such an embodiment makes the filter characteristics insusceptible to parasitic capacitances ascribable to the gate capacitances. This also makes it possible to adjust the filter characteristics by modifying the gm values.

FIG. 5C shows a fourth-order LPF which is formed by adding a fifth transconductance amplifier 66 and a fourth capacitive element 68 to the first gm-C filter unit 32 shown in FIG. 5B. In this instance, the fourth transconductance amplifier 62 is connected with the output of the second transconductance amplifier 38. The fifth transconductance amplifier 66 is arranged between the fourth transconductance amplifier 62 and the third transconductance amplifier. The third capacitive element 64 is arranged between the fourth transconductance amplifier 62 and earth. The fourth capacitive element 68 is arranged between the fifth transconductance amplifier 66 and earth. The fourth transconductance amplifier 62 also receives the signal that is output from itself or from the fifth transconductance amplifier 66. The fifth transconductance amplifier 66 also receives the signal that is output from itself.

In this instance, the ratio of the device area of the second transconductance amplifier 38 with respect to the device area of the fifth transconductance amplifier 66 is related to the ratio of the capacitance of the first capacitive element 40 with respect to the capacitance of the third capacitive element 64 so that the ratios coincide with each other. Furthermore, the ratio of the device area of the second transconductance amplifier 38 with respect to the total device area of the third transconductance amplifier, the fourth transconductance amplifier 62, and the fifth transconductance amplifier 66 is related to the ratio of the capacitance of the first capacitive element 40 with respect to the capacitance of the fourth capacitive element 68 so that the ratios coincide with each other. Also, the ratio of the device area of the second transconductance amplifier 38 with respect to the total device area of the first transconductance amplifier 36, the second transconductance amplifier 38, and the fourth transconductance amplifier 62 is associated with the ratio of the capacitance of the first capacitive element 40 with respect to the capacitance of the second capacitive element 42 so that the ratios coincide with each other. To put it another way, the relationships satisfy the following equations:
C1:C2:C3:C4=1:k2:k3:k4, (19)
S1+S2+S4=k2·S2, (20)
S5=k3·S2, and (21)
S3+S4+S5=k4·S2. (22)

Such an embodiment makes the filter characteristics insusceptible to parasitic capacitances ascribable to the gate capacitances. This also makes it possible to adjust the filter characteristics by modifying the gm values.

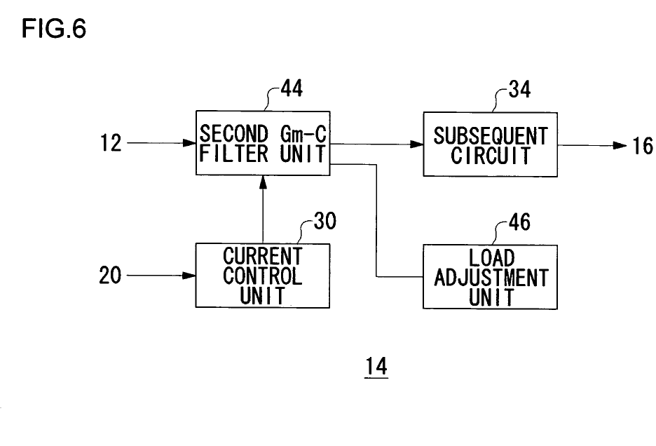

FIG. 6 is a diagram showing a modification of the active filter unit 14 shown in FIG. 4. The active filter unit 14 includes a second gm-C filter unit 44, a load adjustment unit 46, a subsequent circuit 34, and a current control unit 30. In this instance, the subsequent circuit 34 includes a not-shown third transconductance amplifier. The load adjustment unit 46 includes a not-shown fourth transconductance amplifier.

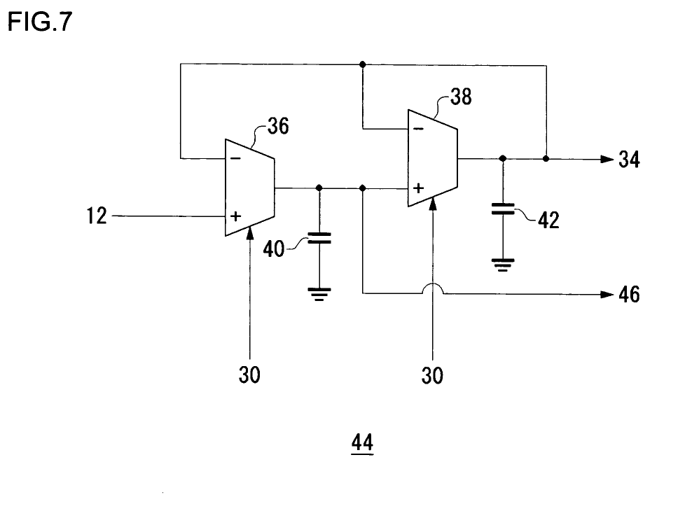

FIG. 7 is a diagram showing an example of the configuration of the second gm-C filter unit 44 shown in FIG. 6. The second gm-C filter unit 44 shown in FIG. 7 has almost the same configuration as that of the first gm-C filter unit 32 shown in FIG. 5A. The difference between the first gm-C filter unit 32 shown in FIG. 5A and that shown in FIG. 7 is that the fourth transconductance amplifier is connected with the output of the first transconductance amplifier 36. Here, the ratio of the total device area of the second transconductance amplifier 38 and the fourth transconductance amplifier 62 with respect to the total device area of the first transconductance amplifier 36, the second transconductance amplifier 38, and the third transconductance amplifier is related to the ratio of the capacitance of the first capacitive element 40 with respect to the capacitance of the second capacitive element 42 so that the ratios coincide with each other. To put it another way, the relationship satisfies the following equations:
C1:C2=1:k, and (23)
S1+S2+S3=k·(S2+S4). (24)

In this case, since there is the gate capacitance of S4, k may be lower than or equal to 1 unless it falls to zero. This increases the degrees of freedom of the device areas. For example, k can be lowered to increase the proportion of the capacitance C1. S2 can also be reduced for additional S4, thereby making the capacitance to be connected with C1 greater.

Such an embodiment makes the filter characteristics insusceptible to parasitic capacitances ascribable to the gate capacitances. This also makes it possible to adjust the filter characteristics by modifying the gm values. Moreover, the provision of the fourth transconductance amplifier 62 as a dummy capacitor can improve the flexibility in designing the devices areas of the transconductance amplifiers and the capacitances of the capacitive elements.

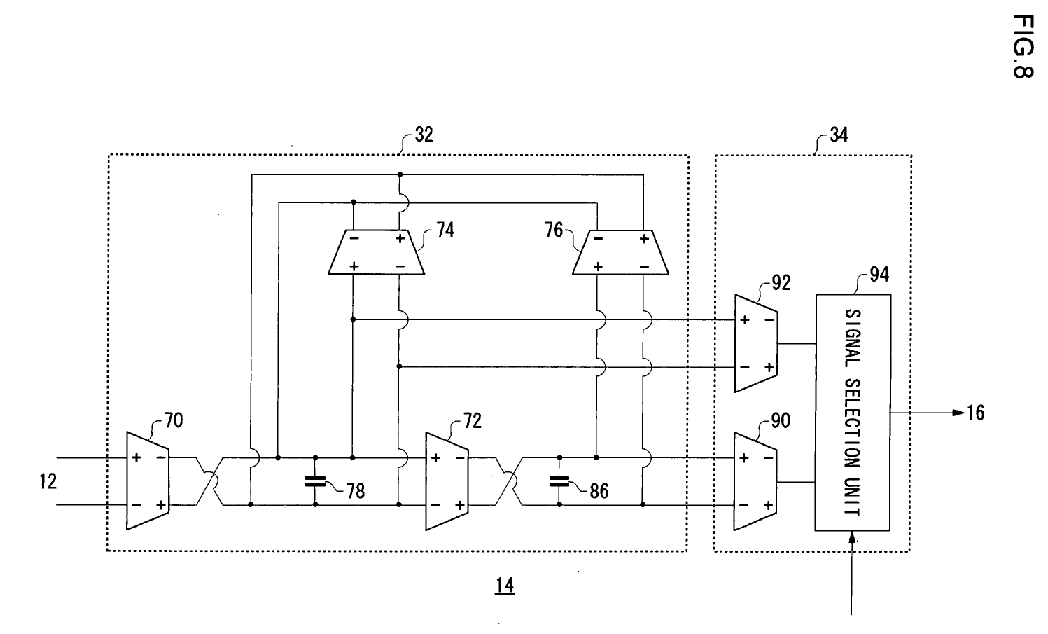

FIG. 8 is a diagram showing another modification of the active filter unit 14 shown in FIG. 4. The active filter unit 14 includes a first gm-C filter unit 32 and a subsequent circuit 34. The first gm-C filter unit 32 includes a sixth transconductance amplifier 70, a seventh transconductance amplifier 72, an eighth transconductance amplifier 74, a ninth transconductance amplifier 76, a fifth capacitive element 78, and a sixth capacitive element 86. The subsequent circuit 34 includes a tenth transconductance amplifier 90, an eleventh transconductance amplifier 92, and a signal selection unit 94. Note that the block corresponding to the central control unit 20 shown in FIG. 1 is omitted from FIG. 8.

According to an instruction from a not-shown management unit or the like, the signal selection unit 94 selects and outputs either one of the signal output from the tenth transconductance amplifier 90 and the signal output from the eleventh transconductance amplifier 92. Here, what is input to the eleventh transconductance amplifier 92 is a signal that is obtained by passing the intermediate frequency band of the signal input from the first filter signal selection unit 12 (band-pass signal). Meanwhile, what is input to the tenth transconductance amplifier 90 is a signal that is obtained by passing the low frequency band of the signal input from the first filter signal selection unit 12 (low-pass signal). The foregoing description has dealt with the case where the subsequent circuit 34 includes the signal selection unit 94. Nevertheless, the subsequent circuit 34 may not include the signal selection unit 94 so that it simply outputs the band-pass signal and low-pass signal output from the first gm-C filter unit 32.

Consider the case where the fifth capacitive element 78 and the sixth capacitive element 86 have capacitances C1 and C2, respectively. Consider also the case where the sixth transconductance amplifier 70, the seventh transconductance amplifier 72, the eighth transconductance amplifier 74, the ninth transconductance amplifier 76, the tenth transconductance amplifier 90, and the eleventh transconductance amplifier 92 have device areas S1, S2, S3, S4, S5, and S6, respectively. The capacitances and the areas are related by the following equations:
C1:C2=1:k, and (25)
S4+S5=k·(S2+S3+S6). (26)

Such an embodiment makes the filter characteristics insusceptible to parasitic capacitances ascribable to the gate capacitances. This also makes it possible to adjust the filter characteristics by modifying the gm values. It should be appreciated that a transconductance amplifier may also be added as a dummy capacitance as in FIG. 7.

As detailed above, the areas of the gate capacitances and the ratios of the capacitances of the respective filters are made constant with respect to each other. This makes it possible to maintain the capacitances, including the parasitic capacitances, of the capacitive elements constant. As a result, desired filter characteristics can be obtained by uniformly adjusting the gm values of the transconductance amplifiers. In general, filter capacitances must be increased to make the gate capacitances relatively smaller in order to reduce errors in the filter characteristics. According to the embodiment of the present invention, however, the filter characteristics can be adjusted to desired values even including the gate capacitances. It is therefore possible to lower the filter capacitances and reduce the circuit areas accordingly. In addition to this, the capacitances can be reduced to lower the gm values of the transconductance amplifiers without affecting ω₀ and Q which determine the filter characteristics. As a result, it is possible to reduce the current consumption of the transconductance amplifiers.

In terms of hardware, these configurations described above can be achieved by an arbitrary computer CPU, a memory, and other LSIs. In terms of software, they can be achieved by a program or the like which is loaded on a memory. The functional blocks shown here are achieved by the cooperation of both the hardware and software. It will thus be understood by those skilled in the art that these functional blocks may be practiced in various forms, including hardware alone, software alone, and a combination thereof.

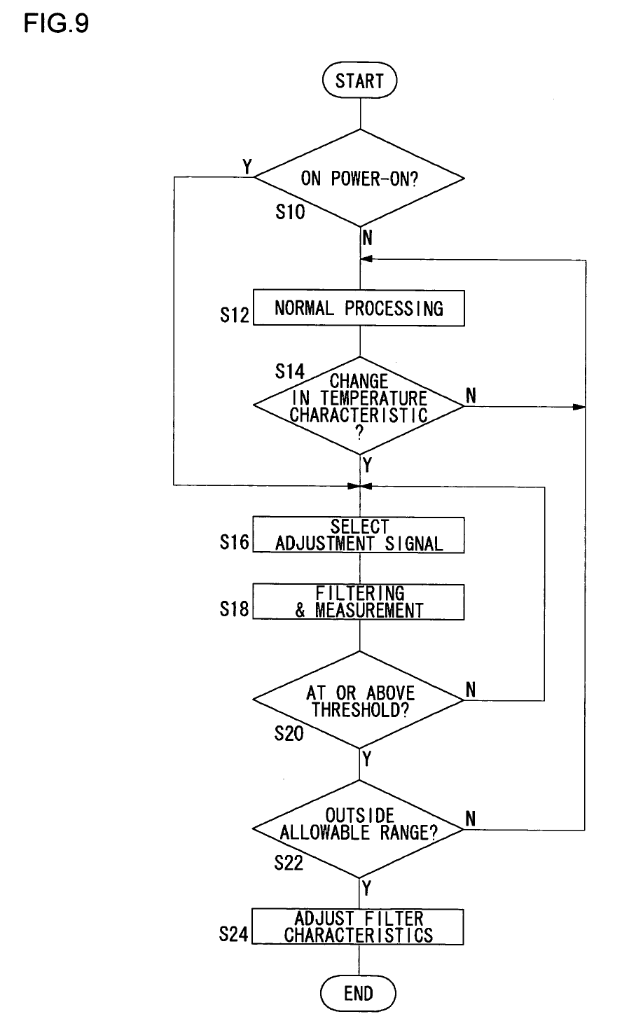

FIG. 9 is a flowchart showing an example of the operation of the central control unit 20 shown in FIG. 2. Initially, the state detection unit 26 detects the state of the communication apparatus 100, and determines whether or not the apparatus has just been powered on (S10). If not on power-on (N at S10), the selection control unit 84 performs normal processing so that the first filter signal selection unit 12 selects the signal output from the reception unit 10 (S12). The selection control unit 84 also makes the second filter signal selection unit 16 output the signal from the active filter unit 14 to the demodulation unit 18. Subsequently, the selection control unit 84 continues the processing of S12 until the state detection unit 26 detects a change in the temperature characteristic of the communication unit 100 (S12, N at S14).

On the other hand, if it is determined that the apparatus has just been powered on (Y at S10), or if it is determined that the temperature characteristic has changed (Y at S14), the selection control unit 84 makes the adjustment signal generating unit 24 generate a plurality of adjustment signals via the adjustment signal selection instruction unit 58. The selection control unit 84 also makes the adjustment signal generating unit 24 select and output any of the adjustment signals to the first filter signal selection unit 12 (S16). The selection control unit 84 also performs adjustment processing so that the first filter signal selection unit 12 selects the adjustment signal that is output from the adjustment signal generating unit 24. The selection control unit 84 also makes the second filter signal selection unit 16 output the signal from the active filter unit 14 to this central control unit 20. In this instance, the active filter unit 14 performs filter processing on the adjustment signal (S18). In the meantime, the signal strength measurement unit 50 measures the signal power of filter-processed adjustment signals output through the second filter signal selection unit 16. The derivation unit 80 also determines attenuations of the measured signal power and a difference therebetween.

In this instance, if the attenuation difference is smaller than a threshold and it is therefore difficult to estimate the cutoff frequency (N at S20), the selection control unit 84 makes the adjustment signal generating unit 24 output another adjustment signal via the filter signal selection instruction unit 56. Meanwhile, if the attenuation difference is greater than or equal to the threshold (Y at S20) and the actual difference is considered to fall within an allowable range with respect to the ideal difference (N at S22), the central control unit 20 moves to the normal processing of S12 since the filter characteristics need not be adjusted. On the other hand, if the actual difference is determined to fall outside the allowable range (Y at S22), the estimation unit 82 estimates the cutoff frequency, and adjusts the filter characteristics of the active filter unit 14 via the adjustment instruction unit 60 (S24).

According to the embodiment of the present invention, the use of the plurality of adjustment signals makes it possible to adjust the filter characteristics accurately without being affected by such factors as process variations and changes in the temperature characteristic. Furthermore, the filter characteristics can be adjusted more accurately by using signals having the cutoff frequency and adjacent frequencies as the reference signals. Determining the attenuations of the respective adjustment signals makes it possible to calculate the cutoff frequency with a simple circuit configuration, and adjust the filter characteristics. If the difference between the attenuations of the adjustment signals is determined to be so small that it is difficult to estimate the cutoff frequency accurately, other adjustment signals are generated. Then, the attenuations of those signals can be used to estimate the cutoff frequency accurately. Depending on the state of the communication apparatus 100, a filter adjustment can also be performed to improve the filter characteristics automatically.

Up to this point, the present invention has been described in conjunction with the embodiment thereof. This embodiment is given solely by way of illustration. It will be understood by those skilled in the art that various modifications may be made to combinations of the foregoing components and processes, and all such modifications are also intended to fall within the scope of the present invention.

The embodiment of the present invention has dealt with second- to fourth-order LPFs. This is not intended to be restrictive, however, and it is possible to use fifth- and higher-order LPFs. HPFs (High-Pass Filters) may also be used.

What is claimed is:

1. An active filter circuit comprising:
an input unit which inputs a signal;
a plurality of active elements connected in series so that the active element to which the signal is input from the input unit comes first;
an active element to which an output of the active element in the final stage out of the plurality of active elements is input;
a plurality of capacitive elements formed on outputs of the respective plurality of active elements; and
a control unit which supplies the plurality of active elements with adjustment currents corresponding to the respective active elements, thereby adjusting the gain of the plurality of active elements, wherein
each of the plurality of active elements also receives a signal that is output from the active element itself or the active element at a subsequent stage, and
wherein ratios between the capacitances of the respective plurality of capacitive elements are related to devices areas of the plurality of active elements.

2. An active filter circuit comprising:
an input unit which inputs a predetermined signal;
a first active element to which the predetermined signal is input from the input unit;
a second active element connected to an output of the first active element;
a third active element to which a signal output from the second active element is input;
a first capacitive element arranged between the output of the first active element and earth;
a second capacitive element arranged between an output of the second active element and earth; and
a control unit which supplies the first active element and the second active element with adjustment currents corresponding to the respective active elements, thereby adjusting gains of the first active element and the second active element, wherein
a signal output from the first active element or the second active element is also input to the first active element,
the signal output from the second active element is also input to the second active element, and
a ratio of a device area of the second active element with respect to a total device area of the first active element, the second active element, and the third active element is related to a ratio of the capacitance of the first capacitive element with respect to the capacitance of the second capacitive element so that the ratios coincide with each other.

3. The active filter circuit according to claim 2, further comprising a fourth active element connected to the output of the first active element, and wherein
a ratio of a total device area of the second active element and the fourth active element with respect to the total device area of the first active element, the second active element, and the third active element is related to the ratio of the capacitance of the first capacitive element with respect to the capacitance of the second capacitive element so that the ratios coincide with each other.

4. The active filter circuit according to claim 2, further comprising:
a fourth active element arranged between the second active element and the third active element; and
a third capacitive element arranged between the fourth active element and earth, and wherein:
the signal output from the fourth active element is also input to the fourth active element;
a ratio of the device area of the second active element with respect to a total device area of the third active element and the fourth active element is related to a ratio of the capacitance of the first capacitive element with respect to the capacitance of the third capacitive element so that the ratios coincide with each other; and
a ratio of the device area of the second active element with respect to a total device area of the first active element, the second active element, and the fourth active element is related to the ratio of the capacitance of the first capacitive element with respect to the capacitance of the second capacitive element so that the ratios coincide with each other.

5. The active filter circuit according to claim 2, further comprising:
a fourth active element and a fifth active element arranged between the second active element and the third active element;
a third capacitive element arranged between the fourth active element and earth; and
a fourth capacitive element arranged between the fifth active element and earth, and wherein:
the output of the second active element is connected with an input of the fourth active element;
an output of the fourth active element is connected with an input of the fifth active element;
an output of the fifth active element is connected with an input of the third active element;
a signal output from the fourth active element or the fifth active element is also input to the fourth active element;
the signal output from the fifth active element is also input to the fifth active element;
a ratio of the device area of the second active element with respect to a device area of the fifth active element is related to a ratio of the capacitance of the first capacitive element with respect to the capacitance of the third capacitive element so that the ratios coincide with each other,
a ratio of the device area of the second active element with respect to a total device area of the third active element, the fourth active element, and the fifth active element is related to a ratio of the capacitance of the first capacitive element with respect to the capacitance of the fourth capacitive element so that the ratios coincide with each other, and
a ratio of the device area of the second active element with respect to a total device area of the first active element, the second active element, and the fourth active element is associated with the ratio of the capacitance of the first capacitive element with respect to the capacitance of the second capacitive element so that the ratios coincide with each other.

6. The active filter circuit according to claim 1, wherein the active elements are transconductance amplifiers.

7. The active filter circuit according to claim 2, wherein the active elements are transconductance amplifiers.
